(19) United States
(12) Patent Application Publication
(10) Pub. No.: US 2009/0032878 A1
(43) Pub. Date: Feb. 5, 2009

(54) Semiconductor device and fabrication method thereof

(76) Inventors: Kentaro Nakanishi, Nara (JP); Takayuki Yamada, Osaka (JP)

Correspondence Address: MCDERMOTT WILL & EMERY LLP, 600 13TH STREET, NW, WASHINGTON, DC, 20005-3096, US

(21) Appl. No.: 11/976,668

(22) Filed: Oct. 26, 2007

(30) Foreign Application Priority Data
Feb. 13, 2007 (JP) 2007-031716

(51) Int. Cl. H01L 21/336; H01L 27/088

(52) U.S. Cl. 257/368; 438/305; 257/E27.06; 257/E21.409

(57) ABSTRACT

A semiconductor device comprises a first gate electrode formed on a first region of a semiconductor substrate, a first impurity layer formed at least below both ends of the first gate electrode in the first region, a first side wall formed on both side surfaces of the first gate electrode, and a second impurity layer formed on both sides of the first side wall as viewed from the first gate electrode in the first region. The first impurity layer includes a first-conductivity type first impurity and a first-conductivity type second impurity having a larger mass number than that of the first impurity.

### CROSS REFERENCE TO RELATED APPLICATIONS

This Non-provisional application claims priority under 35 U.S.C. §119(a) on Patent Application No. 2007-031716 filed in Japan on Feb. 13, 2007, the entire contents of which are hereby incorporated by reference.

### BACKGROUND OF THE INVENTION

1. Field of the Invention

The present invention relates to a semiconductor device capable of securing a high level of driving ability while suppressing the short-channel effect. More particularly, the present invention relates to a semiconductor device and its fabrication method in which, when a plurality of elements having different desired characteristics are formed in a single semiconductor device, a step or steps can be removed while securing the characteristics of each element.

2. Description of the Related Art

In recent semiconductor devices, it is increasingly difficult to suppress the short-channel effect, which is a phenomenon that a threshold voltage decreases as a gate length is reduced by progress in miniaturization. On the other hand, since a higher level of driving ability is required, an impurity profile in the SD (source-drain) extension region of a logic transistor particularly needs to have a high concentration in the vicinity of a substrate surface so that the resistance is reduced and the junction depth is suppressed (i.e., a steep profile).

FIGS. 9A to 9E are cross-sectional views of general steps of fabricating a semiconductor device comprising a MOS transistor as a conventional example.

Initially, as shown in FIG. 9A, a gate electrode 103 made of a conductive film is formed via an insulating film 102 in a predetermined region on a semiconductor substrate 101. Next, as shown in FIG. 9B, impurity implantation is performed with respect to the semiconductor substrate 101 using the gate electrode 103 as a mask to form an SD extension region 104. Next, as shown in FIG. 9C, a side wall 105 is formed which covers side walls of the insulating film 102 and the gate electrode 103. Next, as shown in FIG. 9D, impurity implantation is performed with respect to the semiconductor substrate 101 using the gate electrode 103 and the side wall 105 as a mask to form an S/D region (a source region and a drain region are collectively referred to as this) 106. Thereafter, as shown in FIG. 9E, a semiconductor device is completed after a heat treatment step. In the heat treatment step, impurities in the SD extension region 104 and the S/D region 106 are diffused into a greater depth in the semiconductor substrate 101 than before the heat treatment.

In such a conventional semiconductor device fabricating method, the energy of impurity implantation is extremely reduced so as to obtain the steep profile, which is a commonly used technique. Specifically, by forming a shallow implantation profile as. impla (upon implantation), the junction depth of a final profile after the heat treatment is caused to be shallow. Molecular implantation may also be performed so as to equivalently reduce implantation energy. For example, in the case of PMOS, boron difluoride (BF₂) implantation may be employed instead of boron (B) implantation. In this case, when BF₂ is implanted using the same energy instead of B, this BF₂ implantation is equivalent to B implantation which is performed using about ⅕ of the implantation energy because of the difference between the mass number (11) of B and the molecular weight (49) of BF₂.

Another technique for obtaining the steep profile has also been proposed in which indium having a large mass number is applied to the SD extension region of a PMOS transistor (see, for example, Japanese Unexamined Patent Application Publication No. 2006-49733). The mass number (115) of indium is about ten times larger than the mass number (11) of boron. Therefore, indium has more difficulty in being diffused than boron, so that the steep profile can be expected.

Recent semiconductor devices are also characterized in that a plurality of kinds of transistors need to be formed in the same chip. For example, an input/output (I/O) transistor, an eDRAM cell transistor, a high-frequency transistor and the like need to be provided in the same chip in addition to a logic transistor. Also, regarding the I/O transistor, a plurality of transistors having different power supply voltages may need to be provided in the same semiconductor device. By providing a plurality of transistors having totally different functions in the same semiconductor device, the number of semiconductor devices constituting an electronic apparatus can be reduced, thereby simultaneously achieving high performance and a small size.

### SUMMARY OF THE INVENTION

However, the above-described conventional examples have the following problems.

Firstly, when the energy of impurity implantation is extremely reduced, dose loss during implantation becomes significant. Specifically, when the projected range (Rp) of implantation is smaller than or equal to the film thickness of a residual oxide film existing in a substrate surface, impurities cannot be implanted inside a substrate. Further, in semiconductor processes, ashing or cleaning is repeatedly performed with respect to a substrate surface. Therefore, the substrate surface is eroded, so that implanted impurities are removed. When such implantation dose loss occurs, the concentration of the final impurity profile cannot be sufficiently secured, resulting in a high resistance of the impurity diffusion layer.

Also, since indium has a low activation rate, the amount of electrically active impurities cannot be caused to be at a high concentration. Therefore, it is difficult to achieve a low resistance of the impurity diffusion layer. This is fatal to the SD extension region.

Also, when a plurality of transistors having totally different functions are formed in the same semiconductor device, the number of processing steps is inevitably increased. As a result, process cost increases. Further, if the number of steps is increased, the number of times of the ashing and cleaning steps is increased, so that the degree of erosion of a semiconductor substrate increases, resulting in significant implantation dose loss.

The present invention is provided to solve these problems.

The present invention provides a semiconductor device and its fabrication method in which an impurity profile having a low resistance and a shallow junction which can secure a high level of driving ability while suppressing the short-channel effect can be formed, and further, when a plurality of semiconductor devices having different desired characteristics are formed, a step or steps can be removed while securing the characteristics of each semiconductor device.

A semiconductor device according to the present invention comprises a first gate electrode formed on a first region of a semiconductor substrate, a first impurity layer formed at least below both ends of the first gate electrode in the first region, a first side wall formed on both side surfaces of the first gate electrode, and a second impurity layer formed on both sides of the first side wall as viewed from the first gate electrode in the first region and in contact with the first impurity layer. The first impurity layer includes a first-conductivity type first impurity and a first-conductivity type second impurity having a larger mass number than that of the first impurity.

The first impurity layer may be an SD extension region which is extended to below both ends in a gate length direction of the first gate electrode. The second impurity layer may be an S/D region which is extended to below both ends in the gate length direction of the first side wall.

Note that the second impurity layer preferably includes the first impurity and the second impurity.

According to the semiconductor device of the present invention, since the semiconductor device is fabricated by a fabrication method described below, the first impurity is caused to remain in a relatively shallow region in the semiconductor substrate due to a damage layer formed by the implantation of the second impurity. Thereby, a high impurity concentration is obtained in the vicinity of the substrate surface, resulting in an SD extension region having a low resistance and a shallow junction depth.

Note that the semiconductor device preferably further comprises a second gate electrode formed on the second region of the semiconductor substrate, a second side wall formed on both side surfaces of the second gate electrode, and a third impurity layer formed on both sides of the second side wall as viewed from the second gate electrode in the second region and is extended to below both ends of the second gate electrode.

With such a structure, a transistor having an SD extension region having a low resistance and a shallow junction depth in the vicinity of the semiconductor substrate surface is provided in the first region, and in addition, another transistor is provided in the second region of the semiconductor device. In the transistor in the second region, the third impurity layer (S/D region) is extended to below the second side wall and below both ends in an gate length direction of the second gate electrode, resulting in the single S/D structure. Therefore, an LDD region is not required, so that the number of fabrication steps is reduced as compared to structures which require an LDD region.

The second impurity layer may include the first impurity and the second impurity. The third impurity layer may include the first impurity. A diffusion depth of the third impurity layer may be greater than a diffusion depth of the second impurity layer. Such a structure is effective when a logic transistor is formed in the first region and an I/O transistor is formed in the second region.

The semiconductor device preferably further comprises a second gate electrode formed on the second region of the semiconductor substrate, a fourth impurity layer formed at least below both ends of the second gate electrode in the second region, a second side wall formed on both side surfaces of the second gate electrode, and a fifth impurity layer formed on both sides of the second side wall as viewed from the second gate electrode in the second region and in contact with the fourth impurity layer.

Also with such a structure, a transistor having an SD extension region having a low resistance and a shallow junction depth in the vicinity of the semiconductor substrate surface is provided in the first region, and in addition, another transistor is provided in the second region of the semiconductor device. Note that the fourth impurity layer is preferably extended to below both ends in the gate length direction of the second gate electrode. Also, the fifth impurity layer is preferably extended to below both ends of the second side wall in the gate length direction of the second gate electrode.

The second impurity layer may include the first impurity and the second impurity. The fourth impurity layer may include a third impurity. The fifth impurity layer may include the first impurity. A diffusion depth of the fifth impurity layer may be greater than a diffusion depth of the second impurity layer.

Such a structure is effective, for example, when a logic transistor is formed in the first region and a cell transistor (DRAM) is formed in the second region. In general, cell transistors require a larger reduction in junction leakage than logic transistors. Therefore, as described above, the depth of the fifth impurity layer functioning as an S/D region in the second region is preferably greater than the depth of the second impurity layer functioning as an S/D region in the first region.

The second impurity layer preferably includes the first impurity and the second impurity. The fourth impurity layer preferably includes the second impurity. The fifth impurity layer preferably includes the first impurity and the second impurity.

Such a structure is effective, for example, when a logic transistor is formed in the first region and an I/O transistor is formed in the second region.

Also in the semiconductor device, the second impurity is preferably an element of group III. The element of group III is preferably indium or gallium. Such elements can be used as specific examples of the second impurity of the P type.

The second impurity is preferably an element of group V. The element of group V is preferably antimony. Such elements can be used as specific examples of the second impurity of the N type.

Next, a first semiconductor device fabricating method according to the present invention comprises the steps of (a) forming a gate electrode on a semiconductor substrate, (b) implanting a first-conductivity type first impurity into the semiconductor substrate using the gate electrode as a mask, (c) forming an implantation damage layer on both sides of the gate electrode and in a surface portion of the semiconductor substrate by implanting a first-conductivity type second impurity having a larger mass number than that of the first impurity into the semiconductor substrate using the gate electrode as a mask after the step (b), (d) forming a side wall made of an insulating film on both side surfaces of the gate electrode after the steps (b) and (c), (e) implanting a first-conductivity type third impurity into the semiconductor substrate using the gate electrode and the side wall as a mask, and (f) performing a heat treatment after the step (e).

An extension region which is extended to below both ends in the gate length direction of the gate electrode is formed by the first impurity implanted in the step (b). An S/D region (a source region and a drain region) which is extended to below both ends in the gate length direction of the side wall by the third impurity implanted in the step (d). A transistor including these regions and the gate electrode is provided in the semiconductor substrate.

According to the first semiconductor device fabricating method, the second impurity having a larger mass number than that of the first impurity is implanted into the semiconductor substrate to form the damage layer in the vicinity of the surface of the semiconductor substrate. Therefore, during the heat treatment, the first impurity remains or is redistributed in the damage layer (segregation effect), so that the thermal diffusion of the first impurity into an inner portion of the semiconductor substrate is suppressed. As a result, the first impurity is held at a high concentration in the vicinity of the surface of the semiconductor substrate, a shallow junction depth can be achieved. Thus, a transistor having a shallow junction can be obtained.

Also, since the thermal diffusion is suppressed, the peak position of the concentration of the first impurity during implantation can be set to be deep to some extent from the semiconductor substrate surface. Even in such a case, the distribution of the first impurity after the heat treatment is not excessively diffused into a deep portion of the semiconductor substrate. Thus, by setting the peak position of the first-impurity concentration to be deep to some extent, the influence of dose loss due to substrate surface erosion unavoidable in the fabrication process of semiconductor devices can be reduced. As a result, the concentration of the first impurity after the heat treatment can be held, which is effective to the resistance reduction.

Note that the first impurity is, for example, boron and the second impurity is, for example, indium. When the second impurity is implanted in the step (c), the implantation energy of the second impurity is adjusted so as to form the damage layer at a shallow position in the semiconductor substrate. Thereby, a high concentration of the first impurity can be implanted at a shallow position in the semiconductor substrate.

In the first semiconductor device fabricating method, the step (b) may be performed after the step (c).

In this case, after the damage layer is formed by the implantation of the second impurity in the step (c), the implantation of the first impurity in the step (b) is performed. As a result, the implantation range of the first impurity is reduced due to the presence of the damage layer, so that a high concentration of the first impurity can be implanted at a shallower position in the semiconductor substrate.

A second semiconductor device fabricating method according to the present invention comprises the steps of (a) forming a first gate electrode on a first region of a semiconductor substrate and a second gate electrode on a second region of the semiconductor substrate, (b) implanting a first-conductivity type first impurity into the first region using the first gate electrode as a mask, (c) forming an implantation damage layer on both sides of the first gate electrode and in a surface portion of the first region by implanting a first-conductivity type second impurity having a larger mass number than that of the first impurity into the first region using the first gate electrode as a mask after the step (b), (d) forming a first side wall made of an insulating film on both side surfaces of the first gate electrode and a second side wall made of an insulating film on both side surfaces of the second gate electrode after the steps (b) and (c), (e) implanting a first-conductivity type third impurity into the semiconductor substrate using the first gate electrode, the first side wall, the second gate electrode, and the second side wall as a mask, and (f) performing a heat treatment after the step (e).

Note that conditions for the implantation in the step (e) are preferably set so that, by the step (f), the third impurity in the second region is diffused to below both ends in a gate length direction of the second gate electrode. A diffusion depth of the third impurity in the second region is preferably greater than a diffusion depth of the third impurity in the first region due to the implantation damage layer being formed in the first region.

According to the second semiconductor device fabricating method, a transistor having a shallow junction and a low resistance (the concentration of the first impurity in the vicinity of the substrate surface is high) can be formed in the first region of the semiconductor substrate, as in the first semiconductor device fabricating method. Specifically, an extension region is formed in the first region of the semiconductor substrate by the implantation of the first impurity in the step (b), and an S/D region is formed by the implantation of the third impurity in the step (e). Here, since the damage layer is formed in the first region, the segregation effect occurs during the heat treatment of the step (f), so that the first impurity remains in a shallow region of the semiconductor substrate.

In addition, another transistor can be formed in the second region. Since a damage layer is not formed in the second region, the segregation effect does not occur during the heat treatment in the step (f), so that the third impurity is diffused to a deeper position than in the first region. By setting conditions for the implantation in the step (e) in view of a diffusion depth of the third impurity after the heat treatment, a diffusion layer of the third impurity which is extended to below both ends in the gate length direction of the second gate electrode can be formed as an S/D region.

For example, when an I/O transistor is formed, an impurity diffusion layer called an LDD region conventionally needs to be formed after formation of a gate electrode. In contrast, according to the second semiconductor device fabricating method of the present invention, an S/D region which is extended to below both ends of the second gate electrode can be formed in the second region. Thus, the single S/D structure can be achieved, and the step of forming an LDD region can be removed.

Note that, in conventional semiconductor device fabricating methods, when implantation is performed so as to form an S/D region, an impurity profile can be caused to be deep by increasing implantation energy to form the single S/D structure. In this case, however, all S/D regions which are simultaneously formed have a deep impurity profile. For example, an S/D region in a logic transistor is formed deep, resulting in an increase in the short-channel effect. When S/D regions requiring different impurity profiles are separately formed, the number of steps is increased.

In contrast, in the second semiconductor device fabricating method of the present invention, since the damage layer is formed in the first region, even if impurity implantation is performed in the same step, the impurity profile of the first region can be caused to be shallower than that of the second region. Thereby, the increase of the short-channel effect in the first region can be suppressed.

As described above, the number of steps can be reduced while achieving different impurity profiles between the first region (e.g., a region in which a logic transistor is formed) and the second region (e.g., a region in which an I/O transistor is formed).

Note that, in the second semiconductor device fabricating method of the present invention, the step (b) may be performed after the step (c).

In this case, after the damage layer is formed by the implantation of the second impurity in the step (c), the implantation of the first impurity in the step (b) is performed. As a result, the implantation range of the first impurity is reduced due to the presence of the damage layer, so that a high concentration of the first impurity can be implanted at a shallower position in the semiconductor substrate.

Next, a third semiconductor device fabricating method of the present invention comprises the steps of (a) forming a first gate electrode on a first region of a semiconductor substrate and a second gate electrode on a second region of the semiconductor substrate, (b) implanting a first-conductivity type first impurity into the first region using the first gate electrode as a mask, (c) forming an implantation damage layer on both sides of the first gate electrode and in a surface portion of the first region by implanting a first-conductivity type second impurity having a larger mass number than that of the first impurity into the first region using the first gate electrode as a mask after the step (b), (d) forming a first side wall made of an insulating film on both side surfaces of the first gate electrode and a second side wall made of an insulating film on both side surfaces of the second gate electrode after the steps (b) and (c), (e) implanting a first-conductivity type third impurity into the semiconductor substrate using the first gate electrode, the first side wall, the second gate electrode, and the second side wall as a mask, (f) implanting a first-conductivity type fourth impurity into the second region using the second gate electrode as a mask after the step (a) and before the step (c), and (g) performing a heat treatment after the step (e).

Note that the implantation damage layer formed in the first region is preferably utilized to cause a diffusion depth of the third impurity in the second region to be greater than a diffusion depth of the second impurity in the first region.

According to the third semiconductor device fabricating method of the present invention, the first region of the semiconductor substrate has an impurity profile such that the third impurity remains at a shallow position even after the heat treatment in the step (g) due to the presence of the damage layer. In other words, a transistor having a shallow junction and a low resistance can be formed in the first region, as in the first semiconductor device fabricating method.

In addition, another transistor can be formed in the second region. Since a damage layer is not formed in the second region, a segregation effect does not occur during the heat treatment in the step (g), so that the second impurity is diffused to a deeper position than in the first region.

For example, it is considered that a logic transistor is formed in the first region and a DRAM is formed in the second region. In general, cell transistors require a larger reduction in junction leakage than logic transistors. Therefore, cell transistors need to have an S/D region deeper than that of logic transistors, and have a gentle impurity concentration gradient. In other words, it is necessary to provide different S/D regions between the first region and the second region.

However, according to the third semiconductor device fabricating method of the present invention, since the damage layer is formed in the first region, even when the implantation of the third impurity and the heat treatment are performed with respect to the first region and the second region simultaneously, the third impurity is diffused deeper in the second region than in the first region. In other words, it is not necessary to provide S/D regions of the first region and the second region in separate steps, so that the number of steps can be reduced.

As described above, in the third semiconductor device fabricating method of the present invention, the number of steps can be reduced while achieving different impurity profiles between the first region (e.g., a region in which a logic transistor is formed) and the second region (e.g., a region in which a cell transistor is formed).

In the third semiconductor device fabricating method of the present invention, the step (b) may be performed after the step (c).

In this case, after the damage layer is formed by the implantation of the second impurity in the step (c), the implantation of the first impurity in the step (b) is performed. As a result, the implantation range of the first impurity is reduced due to the presence of the damage layer, so that a high concentration of the first impurity can be implanted at a shallower position in the semiconductor substrate.

Also, in the third semiconductor device fabricating method of the present invention, the step (f) may be performed before the step (b) and the step (c).

When a resist mask is used to selectively implant an impurity into a certain region, ashing, cleaning and the like are required for removal of the resist. In this case, substrate erosion occurs. When impurity implantation (step (b)) is first performed with respect to the first region, substrate erosion occurs in the first region due to ashing, cleaning and the like after selective impurity implantation (step (f)) is performed with respect to the second region, so that dose loss is likely to occur. Therefore, the step (f) is preferably performed before the step (b) and the step (c).

A fourth semiconductor device fabricating method according to the present invention comprises the steps of (a) forming a first gate electrode on a first region of a semiconductor substrate and a second gate electrode on a second region of the semiconductor substrate, (b) implanting a first-conductivity type first impurity into the first region using the first gate electrode as a mask, (c) forming an implantation damage layer on both sides of each of the first gate electrode and the second gate electrode and in a surface portion of the first region by implanting a first-conductivity type second impurity having a larger mass number than that of the first impurity into the semiconductor substrate using the first gate electrode and the second gate electrode as a mask after the step (b), (d) forming a first side wall made of an insulating film on both side surfaces of the first gate electrode and a second side wall made of an insulating film on both side surfaces of the second gate electrode after the steps (b) and (c), (e) implanting a first-conductivity type third impurity into the semiconductor substrate using the first gate electrode, the first side wall, the second gate electrode, and the second side wall as a mask, and (f) performing a heat treatment after the step (e).

According to the fourth semiconductor device fabricating method of the present invention, the first region and the second region of the semiconductor substrate has an impurity profile such that the third impurity remains at a shallow position even after the heat treatment in the step (f) due to the presence of the damage layer. In other words, a transistor having a shallow junction and a low resistance can be formed in the first region, as in the first semiconductor device fabricating method.

In addition, according to the fourth semiconductor device fabricating method, different transistors can be formed in the first region and the second region while reducing the number of steps. For example, it is considered that a logic transistor is formed in the first region and an I/O transistor is formed in the second region.

In the first region, an S/D extension region is formed by the implantation of the first impurity in the step (b). In contrast, in the second region, the second impurity implanted so as to form the damage layer is also used as an impurity for forming an LDD region. Thereby, the step of implantation for forming an LDD region of the second region in the I/O transistor can be removed, resulting in an reduction in the number of steps for fabrication of the semiconductor device.

Note that LDD regions require a lower reduction in resistance than the SD extension region of logic transistors. Therefore, indium or the like having a low activation rate can be used as the third impurity.

Note that, in the fourth semiconductor device fabricating method of the present invention, the step (b) may be performed after the step (c).

In this case, after the damage layer is formed by the implantation of the second impurity in the step (c), the implantation of the first impurity in the step (b) is performed. As a result, the implantation range of the first impurity is reduced due to the presence of the damage layer, so that a high concentration of the first impurity can be implanted at a shallower position in the semiconductor substrate.

Also in the first to fourth semiconductor device fabricating methods of the present invention, the second impurity is preferably an element of group III. Further, the element of group III is preferably indium or gallium. Such elements can be used as specific examples of the second impurity of the P type.

The second impurity is preferably an element of group V. The element of group V is preferably antimony. Such elements can be used as specific examples of the second impurity of the N type.

According to the present invention, a semiconductor device and its fabrication method can be provided in which an impurity profile having a low resistance and a shallow junction which can secure a high level of driving ability while suppressing the short-channel effect can be formed, and further, when a plurality of semiconductor devices having different desired characteristics are formed, a step or steps can be removed while securing the characteristics of each semiconductor device.

### BRIEF DESCRIPTION OF THE DRAWINGS

FIGS. 1A to 1F are cross-sectional views showing steps of fabricating a semiconductor device according to a first embodiment of the present invention.

FIGS. 2A and 2B are diagrams for describing profiles in a depth direction of SD extension regions of the present invention and a conventional semiconductor device.

FIGS. 3A to 3C are cross-sectional views showing steps of fabricating a semiconductor device according to a second embodiment of the present invention.

FIGS. 4A to 4C are cross-sectional views showing steps of fabricating the semiconductor device of the second embodiment, following FIG. 3C.

FIGS. 5A to 5C are cross-sectional views showing steps of fabricating a semiconductor device according to a third embodiment of the present invention.

FIGS. 6A to 6C are cross-sectional views showing steps of fabricating the semiconductor device of the third embodiment, following FIG. 5C.

FIGS. 7A to 7C are cross-sectional views showing steps of fabricating a semiconductor device according to a fourth embodiment of the present invention.

FIGS. 8A to 8C are cross-sectional views showing steps of fabricating the semiconductor device of the fourth embodiment, following FIG. 7C.

FIGS. 9A to 9E are cross-sectional views for describing a conventional semiconductor device fabricating method.

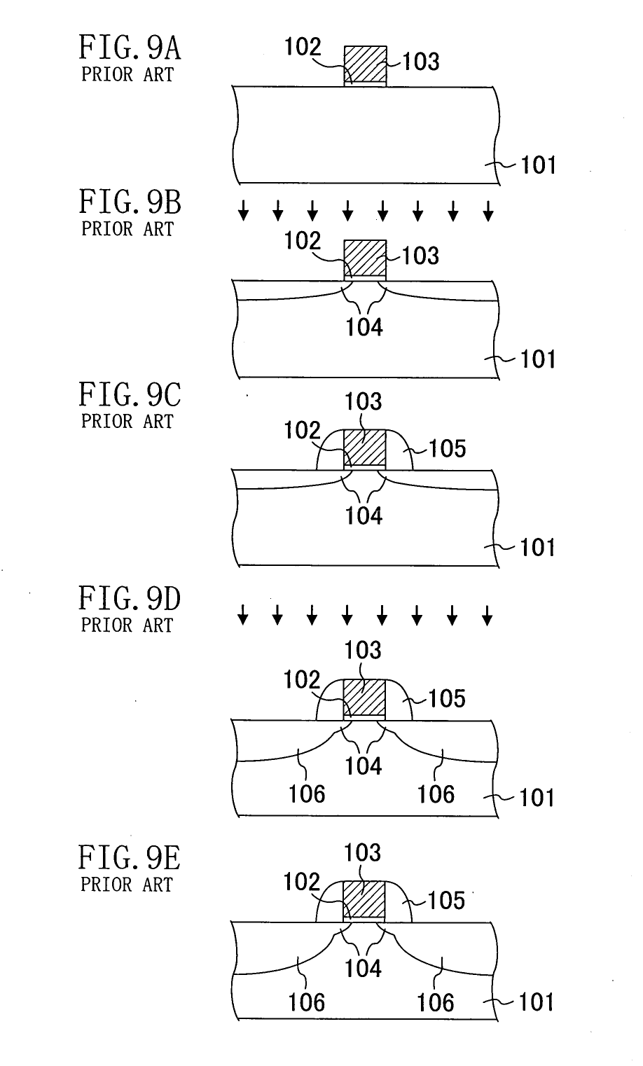

### DETAILED DESCRIPTION OF THE PREFERRED EMBODIMENTS

### First Embodiment

Hereinafter, a semiconductor device and its fabrication method according to a first embodiment of the present invention will be described with reference to the accompanying drawings.

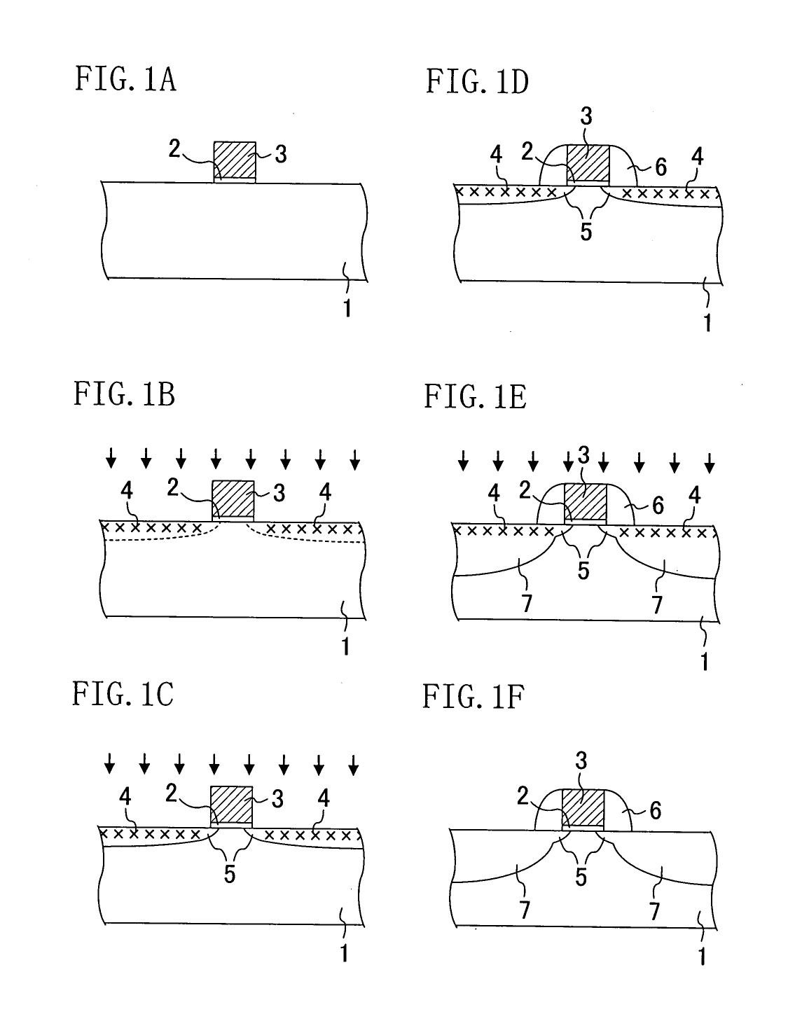

FIGS. 1A to 1F are cross-sectional views showing steps of fabricating the semiconductor device of the first embodiment of the present invention. It is here assumed that a PMOS transistor is formed.

Initially, as shown in FIG. 1A, an insulating film having a film thickness of 2 nm is formed on a semiconductor substrate 1, and a polysilicon film having a film thickness of 120 nm is formed on the insulating film, followed by patterning. Thereby, a gate electrode 3 is provided via a gate insulating film 2 in a desired region of the semiconductor substrate 1. Although a gate oxynitride film, which is produced by forming a silicon oxide film and then subjecting it to a nitriding treatment, is generally used as the gate insulating film 2, other films can be used. For example, a multilayer film composed of a silicon oxide film and a high-k film can be used.

Next, as shown in FIG. 1B, using the gate electrode 3 as a mask, indium is implanted into the semiconductor substrate 1 to provide a damage layer 4 both sides of the gate electrode 3 and in the vicinity of a surface of the semiconductor substrate 1. It is here assumed that conditions for the indium implantation are, for example, such that the acceleration energy is 10 keV and the dose is 1×10¹⁴/cm². Note that, in the damage layer 4, the crystal structure of the semiconductor substrate 1 is changed into an amorphous structure.

Next, as shown in FIG. 1C, using the gate electrode 3 as a mask, boron is implanted into the semiconductor substrate 1 to provide an SD extension region 5 on both side surfaces of the gate electrode 3 and in the vicinity of the surface of the semiconductor substrate 1. It is here assumed that conditions for the boron implantation are, for example, such that the acceleration energy is 0.5 keV and the dose is 5×10¹⁴/cm². The SD extension region 5 is extended to below both ends (in the gate length direction) of the gate electrode 3. In other words, the SD extension region 5 is formed at least below both ends of the gate electrode 3.

In this case, since the amorphous structure is present in the damage layer 4, the implantation range of boron in the semiconductor substrate 1 is reduced. Thereby, the SD extension region 5 can be caused to be shallow. Note that indium can be implanted after the boron implantation.

Next, as shown in FIG. 1D, a side wall spacer (hereinafter referred to as a side wall 6) made of an insulating film is formed on both sides of the gate electrode 3. To do so, a TEOS (tetra ethyl ortho silicate) oxide film having a film thickness of 50 nm is formed on the semiconductor substrate 1, covering the gate electrode 3, followed by etching. Thereby, the side wall 6 is formed which covers both side surfaces of the gate electrode 3.

Next, as shown in FIG. 1E, using the gate electrode 3 and the side wall 6 as a mask, boron is implanted into the semiconductor substrate 1 to provide an S/D region 7 on both sides of the gate electrode 3 and in the semiconductor substrate 1. It is here assumed that conditions for the boron implantation are, for example, such that the acceleration energy is 3 keV and the dose is 3×10¹⁵/cm². The S/D region 7 is extended to below both ends (in the gate length direction of the gate electrode 3) of the side wall 6, contacting the SD extension region 5.

Next, as shown in FIG. 1F, a heat treatment is performed so as to, for example, activate the implanted impurity. Thereafter, silicide formation for reducing the resistance of a surface of the S/D region 7 or the like, wiring formation, and the like are performed, though not illustrated, thereby completing the semiconductor device of this embodiment. Note that the damage layer may be restored (an amorphous structure is put back to a crystal structure) by the heat treatment.

The heat treatment is an important step for activation of the impurity. However, the impurity is thermally diffused during the heat treatment, so that the diffusion depth of the diffusion layer generally increases. As a result, a phenomenon called the short-channel effect occurs, in which a threshold voltage fluctuates, conventionally leading to a deterioration in characteristics.

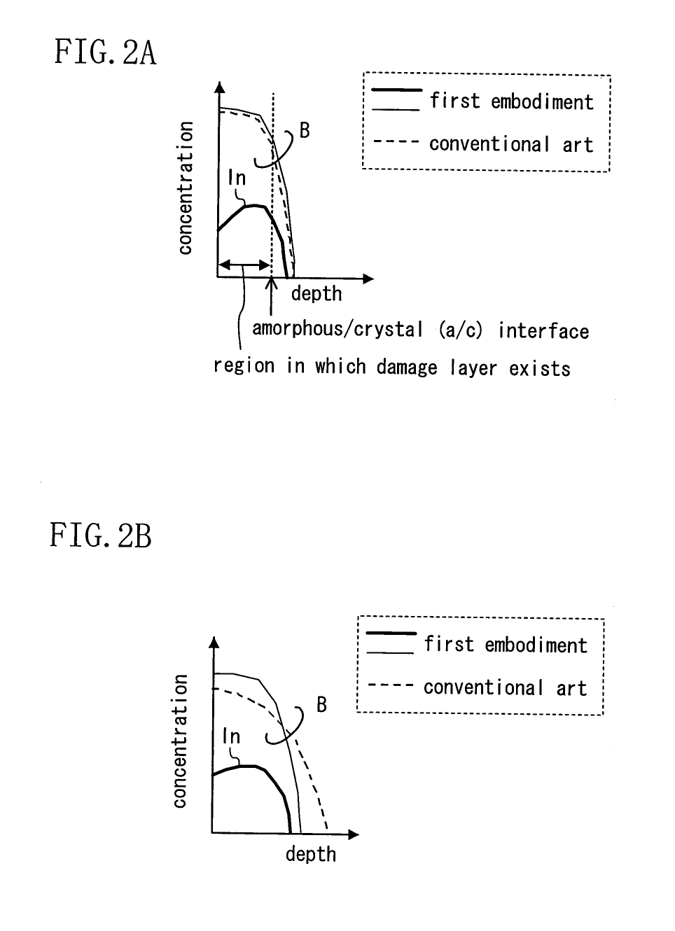

However, according to the semiconductor device fabricating method of this embodiment, such a deterioration in characteristics can be effectively suppressed. This will be hereinafter described with reference to FIGS. 2A and 2B.

FIG. 2A shows impurity profiles in a depth direction, immediately after implantation, of a region where the SD extension region 5 is formed. Note that, in FIG. 2A, the impurity profiles of boron and indium when indium implantation is performed after boron implantation, are indicated by solid lines. Further, an impurity profile in a conventional SD extension region where only boron is implanted, is indicated by a dashed line.

This embodiment and the conventional case have substantially the same boron impurity profile. In this embodiment, in addition to boron, indium is implanted into the vicinity of the surface of the semiconductor substrate 1, thereby introducing a damage layer.

Next, FIG. 2B shows impurity profiles after the heat treatment. As in FIG. 2A, boron and indium profiles of this embodiment are indicated by solid lines, and a conventional boron profile is indicated by a dashed line.

As shown in FIG. 2B, the impurities are diffused due to the heat treatment, resulting in greater diffusion depths than in the case of FIG. 2A. However, in this embodiment, a segregation phenomenon of boron with respect to the damage region occurs, so that thermal diffusion is suppressed. The segregation phenomenon as used herein means that boron remains or is redistributed in the damage region. As a result, in this embodiment, the impurity profile after the heat treatment can be caused to be shallower than in the conventional case. Such a shallow junction, particularly in the SD extension region 5, is effective for suppression of the short-channel effect.

Also, since it is possible to hold a layer into which boron is introduced to a high concentration in the surface of the semiconductor substrate 1, thereby making it possible to reduce the resistance of the diffusion layer. Therefore, the transistor can be caused to have a high level of driving ability.

To achieve a shallow impurity profile after the heat treatment, the energy of implantation is conventionally reduced. However, this method has a disadvantage such that dose loss occurs. Specifically, the implantation range of boron remains within a residual oxide film occurring in the substrate surface. Also, boron implanted in the substrate surface may be removed by an influence of substrate erosion occurring in the fabrication process of the semiconductor device (the substrate surface is eroded during the process).

In contrast, in the case of the semiconductor device fabricating method of this embodiment, conditions for the indium implantation are set so that the damage layer 4 remains in the surface of the semiconductor substrate 1 even when substrate erosion occurs. Therefore, even when boron is implanted to a somewhat great depth from the surface of the semiconductor substrate 1, the impurity profile can be caused to be shallow by utilizing the segregation phenomenon. As a result, a shallow junction can be achieved without loss of an impurity-implanted layer due to substrate erosion.

Note that, in this embodiment, since the indium implantation (FIG. 1B) is performed prior to the boron implantation (FIG. 1C), the implantation range of boron is reduced by the amorphous structure of the damage layer 4, whereby the resultant impurity profile is steeper than those of FIGS. 2A and 2B.

As also described above, as is different from this embodiment, the indium implantation step of FIG. 1B and the boron implantation step of FIG. 1C can be performed in the reverse order. In this case, the implantation range of boron is not reduced. However, the boron segregation phenomenon during the heat treatment occurs as is similar to when the step of FIG. 1C is performed after the step of FIG. 1B.

As described above, according to this embodiment, a semiconductor device comprising the SD extension region 5 having a shallow junction can be fabricated.

### Second Embodiment

Next, a semiconductor device and its fabrication method according to a second embodiment of the present invention will be described with reference to the drawings.

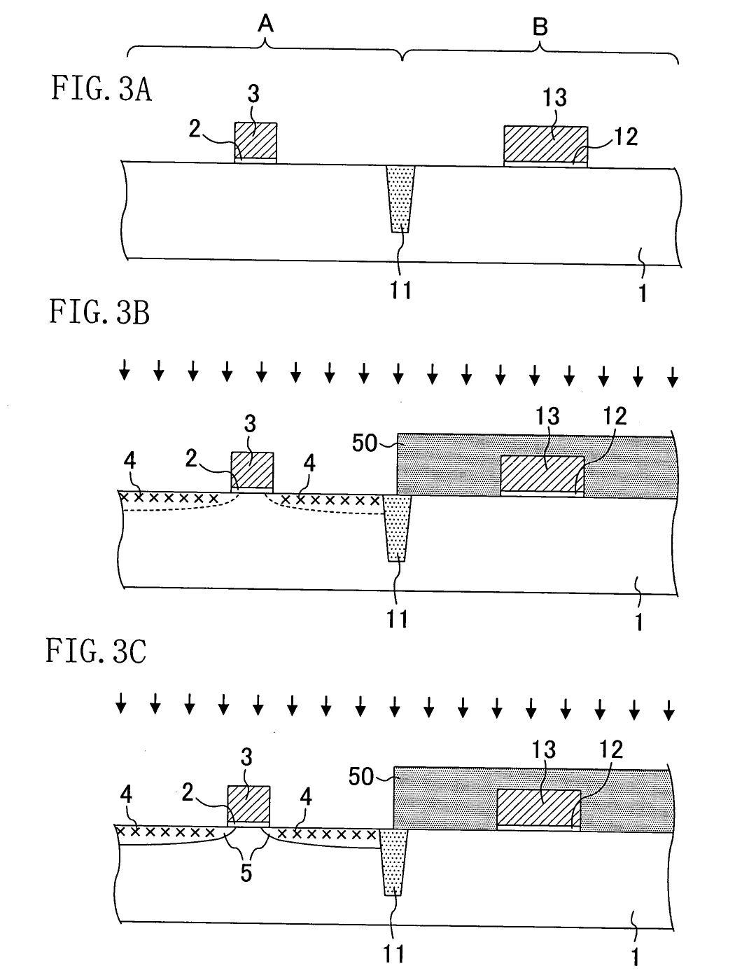

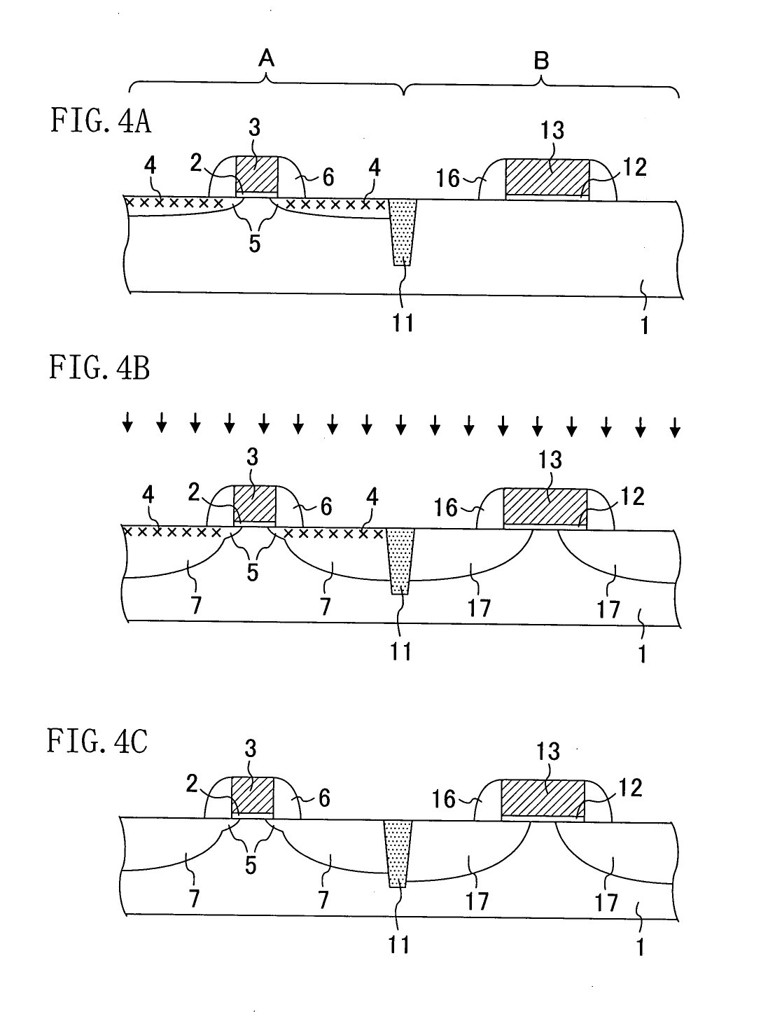

FIGS. 3A to 3C and FIGS. 4A to 4C are cross-sectional views of steps for describing the semiconductor device fabricating method of this embodiment. As an example, it is here assumed that a logic transistor having the PMOS structure is formed in a region A of a semiconductor substrate 1, and an I/O transistor having the PMOS structure is formed in a region B of the semiconductor substrate 1. Note that the transistor formed in the region A is similar to the PMOS transistor formed in the first embodiment.

Initially, as shown in FIG. 3A, a gate electrode 3 having a film thickness of 120 nm is formed via a gate insulating film 2 having a film thickness of 2 nm in the region A of the semiconductor substrate 1 whose surface is sectioned by an isolation region 11. A gate electrode 13 having a film thickness of 120 nm is formed via a gate insulating film 12 having a film thickness of 7 nm in the region B. The gate insulating films 2 and 12 are generally a gate oxynitride film which is obtained by subjecting a silicon oxide film to a nitriding treatment. Alternatively, for example, a multilayer film composed of a silicon oxide film and a high-k film can be used. The gate electrodes 3 and 13 are here formed of a polysilicon film.

Next, as shown in FIG. 3B, a resist 50 is formed as a mask in the region B, followed by indium implantation. Thereby, in the region A, indium is implanted into both sides of the gate electrode 3 to introduce a damage layer 4 into the vicinity of the surface of the semiconductor substrate 1. It is here assumed that conditions for the indium implantation are, for example, such that the acceleration energy is 10 keV and the dose is 1×10¹⁴/cm². Due to the presence of the resist 50, indium is not implanted into the region B.

Next, as shown in FIG. 3C, boron implantation is performed while the resist 50 remains. Thereby, in the region A, boron is implanted into both sides of the gate electrode 3 to form an SD extension region 5. It is here assumed that conditions for the boron implantation are, for example, such that the acceleration energy is 0.5 keV and the dose is 5×10¹⁴/cm². The SD extension region 5 is also extended to below the gate electrode 3. In other words, the SD extension region 5 is formed below both ends of the gate electrode 3.

In this case, since the damage layer 4 has an amorphous structure, the implantation range of boron with respect to the semiconductor substrate 1 is reduced. Thereby, the SD extension region 5 can be caused to be formed shallow. Note that the indium implantation can be performed after the boron implantation.

Next, as shown in FIG. 4A, after the resist 50 is removed, a side wall 6 is formed on both sides of the gate electrode 3 in the region A, while a side wall 16 is formed on both sides of the gate electrode 13 in the region B. To do so, a TEOS film having a film thickness of 50 nm is deposited so as to cover the gate electrodes 3 and 13, and thereafter, is etched, leaving a portion thereof as the side walls 6 and 16 on side surfaces of the gate electrode 3 and 13, respectively.

Next, as shown in FIG. 4B, using the gate electrode 3 and 13 and the side wall 6 and 16 as a mask, boron is implanted into the region A and the region B of the semiconductor substrate 1. Thereby, an S/D region 7 is formed on both sides of the gate electrode 3 and in contact with the SD extension region 5 in the region A, while an S/D region 17 is formed on both sides of the gate electrode 13 in the region B. It is here assumed that conditions for the boron implantation are, for example, such that the acceleration energy is 4 keV and the dose is 3×10¹⁵/cm².

Next, as shown in FIG. 4C, a heat treatment is performed so as to, for example, activate the implanted impurity. Thereafter, silicide formation for reducing the resistance of surfaces of the S/D regions 7 and 17 or the like, wiring formation, and the like are performed, though not illustrated, thereby completing the semiconductor device of this embodiment.

In this embodiment, in the region A, an effect similar to the transistor formation of the first embodiment is obtained. Specifically, a boron segregation phenomenon occurs due to the damage layer 4 formed by the indium implantation, so the SD extension region 5 can have a shallow junction having a high concentration of boron in the surface of the semiconductor substrate 1.

In addition, a transistor having a structure different from that in the region A can be formed in the region B. The boron implantation of FIG. 4B and the heat treatment of FIG. 4C are each performed simultaneously with respect to the region A and the region B, however, the S/D region 17 in the region B is deeper than the S/D region 7 in the region A (see FIG. 4C). This is because a damage layer is not formed in the region B, so that the boron segregation phenomenon does not occur, and therefore, the thermal diffusion of boron is not suppressed.

Also, during the boron implantation of FIG. 4B, conditions for the implantation are set so that the S/D region 17 is extended to below both ends in the gate length direction of the gate electrode 13. Thereby, the I/O transistor formed in the region B can have the single S/D structure. In this case, an LDD region, which is conventionally provided, is not required. Therefore, the step of forming the LDD region can be removed, thereby making it possible to simplify the fabrication process of the semiconductor device.

### Third Embodiment

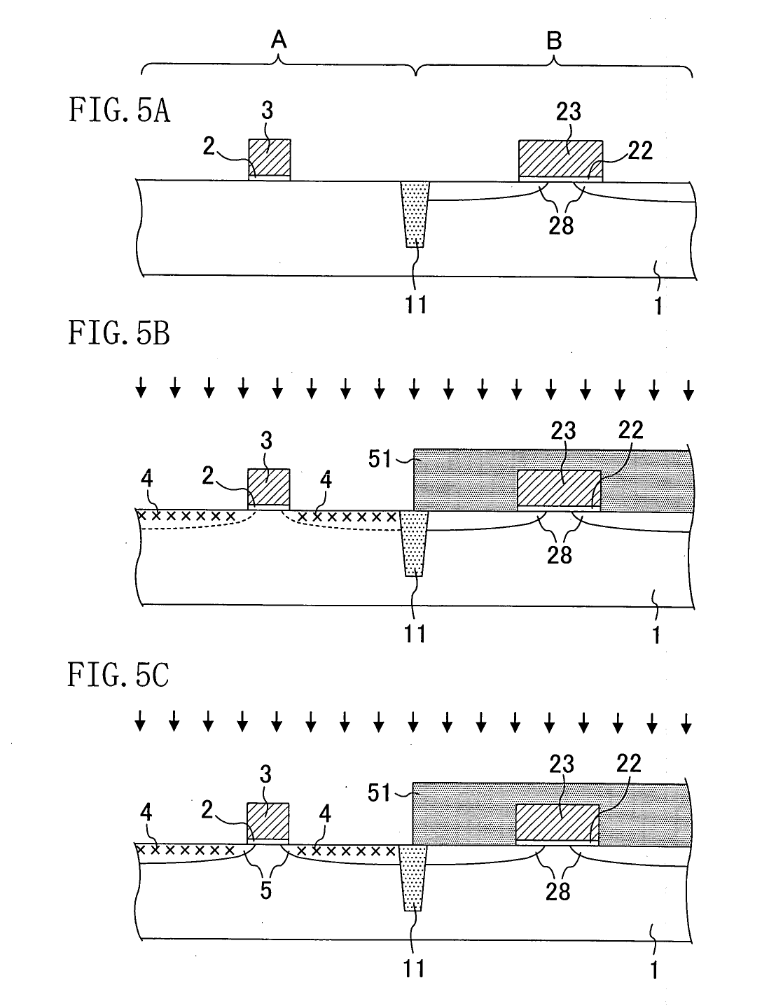

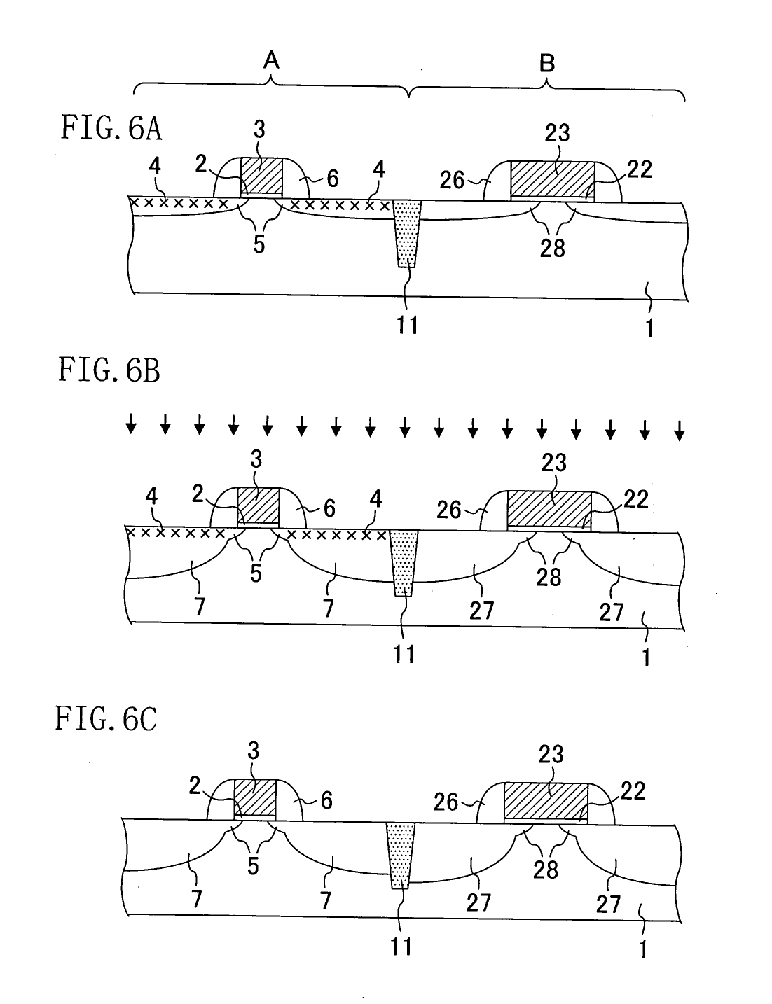

Hereinafter, a semiconductor device and its fabrication method according to a third embodiment of the present invention will be described with reference to the drawings. FIGS. 5A to 5C and FIGS. 6A to 6C are cross-sectional view of steps for describing the semiconductor device fabricating method of this embodiment. As an example, it is here assumed that a logic transistor having the PMOS structure is formed in a region A of a semiconductor substrate 1, and a cell transistor having the PMOS structure is formed in a region B. Note that the transistor formed in the region A is similar to the PMOS transistor formed in the first embodiment.

Initially, as shown in FIG. 5A, a gate electrode 3 having a film thickness of 120 nm is formed via a gate insulating film 2 having a film thickness of 2 nm in the region A of the semiconductor substrate 1 whose surface is sectioned by an isolation region 11. A gate electrode 23 having a film thickness of 120 nm is formed via a gate insulating film 22 having a film thickness of 7 nm in the region B. Materials for these parts are similar to those of the gate insulating films 2 and 12 and the gate electrodes 3 and 13 of the second embodiment.

In the region B, boron implantation is performed using the gate electrode 23 as a mask. Thereby, an LDD region 28 is formed on both sides of the gate electrode 23 in the region B and in the vicinity of a surface of the semiconductor substrate 1. It is here assumed that conditions for the boron implantation are, for example, such that the acceleration energy is 15 keV and the dose is 5×10¹³/cm². The LDD region 28 is also extended to below both ends in the gate length direction of the gate electrode 23.

Next, as shown in FIG. 5B, a resist 51 is formed as a mask in the region B, followed by indium implantation. Thereby, in the region A, indium is implanted into both sides of the gate electrode 3 to introduce a damage layer 4 into the vicinity of the surface of the semiconductor substrate 1. It is here assumed that condition for the indium implantation are, for example, such that the acceleration energy is 10 keV and the dose is 1×10¹⁴/cm². Since the resist 51 is provided, indium is not implanted into the region B.

Next, as shown in FIG. 5C, boron implantation is performed while the resist 51 remains. Thereby, in the region A, boron is implanted into both sides of the gate electrode 3 to form an SD extension region 5. It is here assumed that conditions for the boron implantation are, for example, such that the acceleration energy is 0.5 keV and the dose is 5×10¹⁴/cm². The SD extension region 5 is also extended to below both ends in the gate length direction of the gate electrode 3.

As in the first and second embodiments, due to the damage layer 4 having an amorphous structure, the implantation range of boron is reduced and the SD extension region 5 has a shallow junction. Note that, also in this embodiment, the indium implantation can be formed after the boron implantation.

Next, as shown in FIG. 6A, after the resist 51 is removed, side walls 6 and 26 are formed to cover the gate electrodes 3 and 23, respectively. To do so, a TEOS film having a film thickness of 50 nm is deposited, and thereafter, is etched, leaving a portion thereof only on side surfaces of the gate electrodes 3 and 23.

Next, as shown in FIG. 6B, boron is implanted into the region A and the region B of the semiconductor substrate 1. Thereby, an S/D region 7 is formed on both sides of the gate electrode 3 and in contact with the SD extension region 5 in the region A, while an S/D region 27 is formed on both sides of the gate electrode 23 in the region B. It is here assumed that conditions for the boron implantation are, for example, such that the acceleration energy is 4 keV and the dose is 3×10¹⁵/cm². Note that the S/D regions 7 and 27 are extended to below both ends of the respective side walls 6 and 26 (in the gate length direction of the gate electrodes 3 and 33), respectively.

Next, as shown in FIG. 6C, a heat treatment is performed so as to, for example, activate the implanted impurity. Thereafter, silicide formation, wiring formation, and the like are performed, though not illustrated, thereby completing the semiconductor device of this embodiment.

In this embodiment, an effect similar to the transistor formation of the first embodiment is obtained in the region A. Specifically, the boron segregation phenomenon occurs due to the damage layer 4, so the SD extension region 5 can have a shallow junction having a high concentration of boron in the surface of the semiconductor substrate 1.

Also, a transistor having a structure different from that in the region A can be formed in the region B. Since a damage layer is not formed in the region B, the boron implantation of FIG. 6B and the heat treatment of FIG. 6C are each performed with respect to the region A and the region B in equal amounts, however, the S/D region 27 in the region B is deeper than the S/D region 7 in the region A (see FIG. 6C).

In general, cell transistors require a higher level of suppression of junction leakage than logic transistors. To suppress junction leakage, it is effective to form a deep S/D region. On the other hand, for logic transistors, a deep S/D region should be avoided so as to suppress the short-channel effect. Therefore, conventionally, the S/D region of a cell transistor and the S/D region of a logic transistor are separately subjected to implantation.

In contrast, according to the semiconductor device fabricating method of this embodiment, a plurality of S/D regions having different depths can be formed without performing separate implantations.

As described above, for example, when a logic transistor and a cell transistor are formed in the same the semiconductor substrate 1, different desired characteristics can be achieved and the number of fabrication steps can be reduced.

### Fourth Embodiment

Next, a semiconductor device and its fabrication method according to a fourth embodiment of the present invention will be described with reference to the drawings.

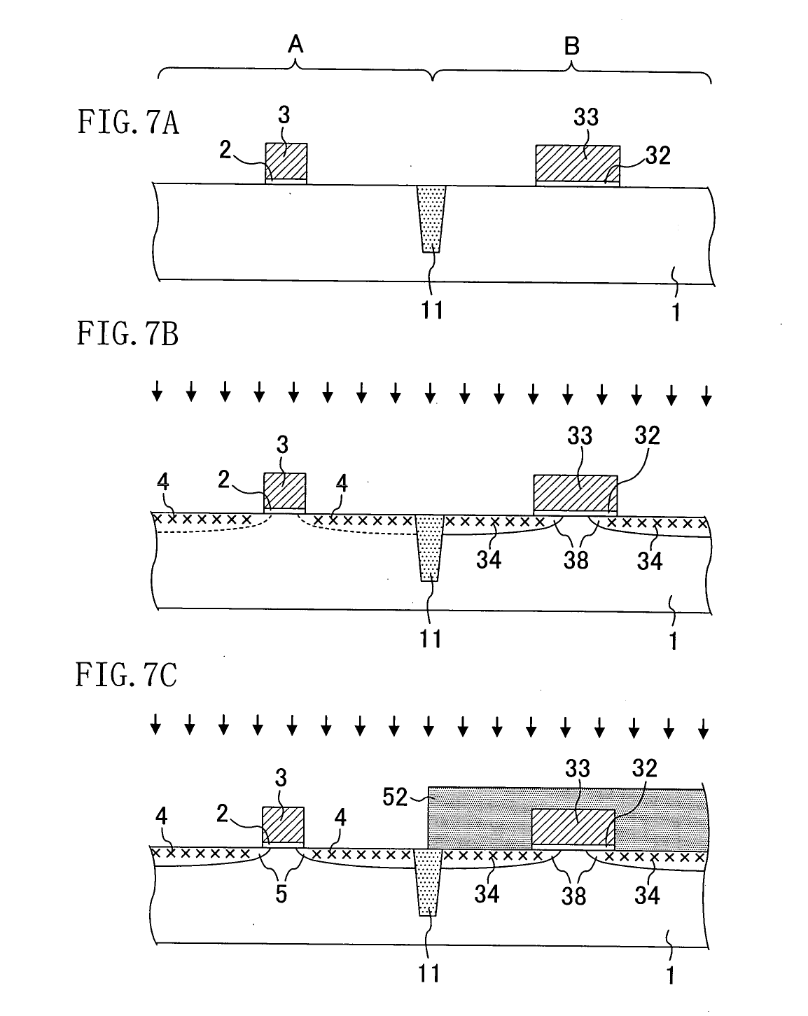

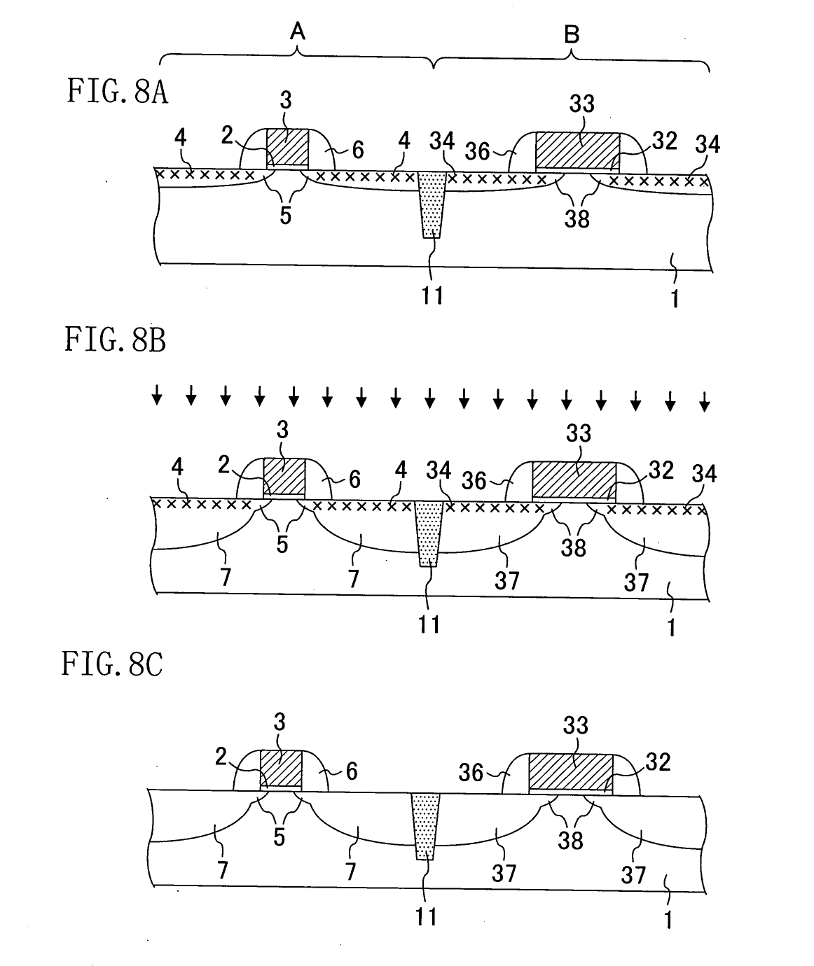

FIGS. 7A to 7C and FIGS. 8A to 8C are cross-sectional views of steps for describing the semiconductor device fabricating method of this embodiment. As an example, it is here assumed that a logic transistor having the PMOS structure is formed in a region A of a semiconductor substrate 1, and an I/O transistor having the PMOS structure is formed in a region B. Note that the transistor formed in the region A is similar to the PMOS transistor formed in the first embodiment.

Initially, as shown in FIG. 7A, a gate electrode 3 having a film thickness of 120 nm is formed via a gate insulating film 2 having a film thickness of 2 nm in the region A of the semiconductor substrate 1 whose surface is sectioned by an isolation region 11. A gate electrode 33 having a film thickness of 120 nm is formed via a gate insulating film 32 having a film thickness of 7 nm in the region B. As in the first to third embodiments, the gate insulating films 2 and 32 are formed of a gate oxynitride film, a multilayer film composed of a silicon oxide film and a high-k film, or the like, and the gate electrodes 3 and 33 are formed of polysilicon.

Next, as shown in FIG. 7B, using the gate electrodes 3 and 13 as a mask, indium is implanted into the region A and the region B of the semiconductor substrate 1, respectively. It is here assumed that conditions for the indium implantation are, for example, such that the acceleration energy is 20 keV and the dose is 1×10¹⁴/cm².

Thereby, a damage layer 4 is formed on both sides of the gate electrode 3 in the region A, while a damage layer 34 is introduced into both sides of the gate electrode 33 in the region B. Further, in the region B, the implanted indium is also used so as to form an LDD region 34. The LDD region 34 is extended to below both ends in the gate length direction of the gate electrode 33.

Next, as shown in FIG. 7C, a resist 52 is formed as a mask in the region B, followed by boron implantation. It is here assumed that conditions for the boron implantation are, for example, such that the acceleration energy is 0.5 keV and the dose is 5×10¹⁴/cm². Thereby, boron is implanted into both sides of the gate electrode 3 in the region A to form an SD extension region 5. The SD extension region 5 is extended to below both ends in the gate length direction of the gate electrode 3.

In this case, as in the first to third embodiments, the implantation range of boron is reduced due to an amorphous structure in the damage layer 4, so that the SD extension region 5 can be formed shallow. Note that the indium implantation can be performed after the boron implantation.

Next, as shown in FIG. 8A, after the resist 52 is removed, a side wall 6 is formed on both sides of the gate electrode 3 in the region A, while a side wall 36 is formed on both sides of the gate electrode 33 in the region B. To do so, a TEOS oxide film having a film thickness of 50 nm is deposited, and thereafter, is etched, leaving a portion thereof so as to cover side surfaces of the gate electrodes 3 and 33.

Next, as shown in FIG. 8B, using the gate electrodes 3 and 13 and the side walls 6 and 16 as a mask, boron is implanted into the region A and the region B of the semiconductor substrate 1. Thereby, an S/D region 7 is formed on both sides of the gate electrode 3 in the region A, while an S/D region 37 is formed on both sides of the gate electrode 33 in the region B. It is here assumed that conditions for the boron implantation are, for example, such that the acceleration energy is 3 keV and the dose is 3×10¹⁵/cm². The S/D regions 7 and 37 are extended to below both ends in the gate length direction of the respective side walls 6 and 36, respectively.

Next, as shown in FIG. 8C, a heat treatment is performed so as to, for example, activate the implanted impurity. Thereafter, silicide formation, wiring formation, and the like are performed, though not illustrated, thereby completing the semiconductor device of this embodiment.

In this embodiment, an effect similar to the transistor formation of the first embodiment is obtained in the region A. Specifically, the boron segregation phenomenon occurs due to the damage layer 4, so the SD extension region 5 can have a shallow junction having a high concentration of boron in the surface of the semiconductor substrate 1.

Also, in the region B, indium which is implanted so as to form the damage layer 34 can be used to form the LDD region 34 of the I/O transistor. The number of steps can be reduced as compared to the conventional art in which the damage layer 34 and the LDD region 34 are formed by separate steps. The activation rate of indium is lower than that of boron. Nevertheless, since the requirement of a low resistance of the LDD region is generally less significant as compared to the SD extension region of a logic transistor, such an arrangement is possible.

In the first to fourth embodiments described above, the materials, dimensions, fabrication conditions and the like for the parts are only for illustrative purposes, and the present invention is not limited to these. Although a combination of a logic transistor, an I/O transistor, a cell transistor and the like has been described as an example, other transistors and a combination thereof can be used. A similar method can be used when an NMOS is formed instead of a PMOS.

What is claimed is:

1. A semiconductor device comprising:
a first gate electrode formed on a first region of a semiconductor substrate;
a first impurity layer formed at least below both ends of the first gate electrode in the first region;
a first side wall formed on both side surfaces of the first gate electrode; and
a second impurity layer formed on both sides of the first side wall as viewed from the first gate electrode in the first region and in contact with the first impurity layer,
wherein the first impurity layer includes a first-conductivity type first impurity and a first-conductivity type second impurity having a larger mass number than that of the first impurity.

2. The semiconductor device of claim 1, wherein
the second impurity layer includes the first impurity and the second impurity.

3. The semiconductor device of claim 1, further comprising:
a second gate electrode formed on the second region of the semiconductor substrate;
a second side wall formed on both side surfaces of the second gate electrode; and
a third impurity layer formed on both sides of the second side wall as viewed from the second gate electrode in the second region and is extended to below both ends of the second gate electrode.

4. The semiconductor device of claim 3, wherein
the second impurity layer includes the first impurity and the second impurity,
the third impurity layer includes the first impurity, and
a diffusion depth of the third impurity layer is greater than a diffusion depth of the second impurity layer.

5. The semiconductor device of claim 1, further comprising:
a second gate electrode formed on the second region of the semiconductor substrate;
a fourth impurity layer formed at least below both ends of the second gate electrode in the second region,
a second side wall formed on both side surfaces of the second gate electrode; and
a fifth impurity layer formed on both sides of the second side wall as viewed from the second gate electrode in the second region and in contact with the fourth impurity layer.

6. The semiconductor device of claim 5, wherein
the second impurity layer includes the first impurity and the second impurity,
the fourth impurity layer includes a third impurity,
the fifth impurity layer includes the first impurity, and
a diffusion depth of the fifth impurity layer is greater than a diffusion depth of the second impurity layer.

7. The semiconductor device of claim 5, wherein
the second impurity layer includes the first impurity and the second impurity,
the fourth impurity layer includes the second impurity, and
the fifth impurity layer includes the first impurity and the second impurity.

8. The semiconductor device of claim 1, wherein
the second impurity is an element of group III.

9. The semiconductor device of claim 8, wherein
the element of group III is indium or gallium.

10. The semiconductor device of claim 1, wherein
the second impurity is an element of group V.

11. The semiconductor device of claim 10, wherein
the element of group V is antimony.

12. A method for fabricating a semiconductor device, comprising the steps of:
(a) forming a gate electrode on a semiconductor substrate;
(b) implanting a first-conductivity type first impurity into the semiconductor substrate using the gate electrode as a mask;
(c) forming an implantation damage layer on both sides of the gate electrode and in a surface portion of the semiconductor substrate by implanting a first-conductivity type second impurity having a larger mass number than that of the first impurity into the semiconductor substrate using the gate electrode as a mask after the step (b);
(d) forming a side wall made of an insulating film on both side surfaces of the gate electrode after the steps (b) and (c);
(e) implanting a first-conductivity type third impurity into the semiconductor substrate using the gate electrode and the side wall as a mask; and
(f) performing a heat treatment after the step (e).

13. The method of claim 12, wherein
the step (b) is performed after the step (c).

14. A method for fabricating a semiconductor device, comprising:
(a) forming a first gate electrode on a first region of a semiconductor substrate and a second gate electrode on a second region of the semiconductor substrate;
(b) implanting a first-conductivity type first impurity into the first region using the first gate electrode as a mask;
(c) forming an implantation damage layer on both sides of the first gate electrode and in a surface portion of the first region by implanting a first-conductivity type second impurity having a larger mass number than that of the first impurity into the first region using the first gate electrode as a mask after the step (b);
(d) forming a first side wall made of an insulating film on both side surfaces of the first gate electrode and a second side wall made of an insulating film on both side surfaces of the second gate electrode after the steps (b) and (c);
(e) implanting a first-conductivity type third impurity into the semiconductor substrate using the first gate electrode, the first side wall, the second gate electrode, and the second side wall as a mask; and
(f) performing a heat treatment after the step (e).

15. The method of claim 14, wherein
conditions for the implantation in the step (e) are set so that, by the step (f), the third impurity in the second region is diffused to below both ends in a gate length direction of the second gate electrode, and
a diffusion depth of the third impurity in the second region is greater than a diffusion depth of the third impurity in the first region due to the implantation damage layer being formed in the first region.

16. The method of claim 14, wherein
the step (b) is performed after the step (c).

17. A method for fabricating a semiconductor device, comprising the steps of:
(a) forming a first gate electrode on a first region of a semiconductor substrate and a second gate electrode on a second region of the semiconductor substrate;
(b) implanting a first-conductivity type first impurity into the first region using the first gate electrode as a mask;
(c) forming an implantation damage layer on both sides of the first gate electrode and in a surface portion of the first region by implanting a first-conductivity type second impurity having a larger mass number than that of the first impurity into the first region using the first gate electrode as a mask after the step (b);
(d) forming a first side wall made of an insulating film on both side surfaces of the first gate electrode and a second side wall made of an insulating film on both side surfaces of the second gate electrode after the steps (b) and (c);
(e) implanting a first-conductivity type third impurity into the semiconductor substrate using the first gate electrode, the first side wall, the second gate electrode, and the second side wall as a mask;
(f) implanting a first-conductivity type fourth impurity into the second region using the second gate electrode as a mask after the step (a) and before the step (c); and
(g) performing a heat treatment after the step (e).

18. The method of claim 17, wherein
the implantation damage layer formed in the first region is utilized to cause a diffusion depth of the second impurity in the second region to be greater than a diffusion depth of the second impurity in the first region.

19. The method of claim 17, wherein
the step (b) is performed after the step (c).

20. The method of claim 17, wherein
the step (f) is performed before the steps (b) and (c).

21. A method for fabricating a semiconductor device, comprising:
(a) forming a first gate electrode on a first region of a semiconductor substrate and a second gate electrode on a second region of the semiconductor substrate;
(b) implanting a first-conductivity type first impurity into the first region using the first gate electrode as a mask;
(c) forming an implantation damage layer on both sides of each of the first gate electrode and the second gate electrode and in a surface portion of the first region by implanting a first-conductivity type second impurity having a larger mass number than that of the first impurity into the semiconductor substrate using the first gate electrode and the second gate electrode as a mask after the step (b);
(d) forming a first side wall made of an insulating film on both side surfaces of the first gate electrode and a second side wall made of an insulating film on both side surfaces of the second gate electrode after the steps (b) and (c);
(e) implanting a first-conductivity type third impurity into the semiconductor substrate using the first gate electrode, the first side wall, the second gate electrode, and the second side wall as a mask; and
(f) performing a heat treatment after the step (e).

22. The method of claim 21, wherein
the step (b) is performed after the step (c).

23. The method of claim 12, wherein
the second impurity is an element of group III.

24. The method of claim 23, wherein
the element of group III is indium or gallium.

25. The method of claim 12, wherein
the second impurity is an element of group V.

26. The method of claim 25, wherein
the element of group V is antimony.

27. The method of claim 14, wherein
the second impurity is an element of group III.

28. The method of claim 27, wherein
the element of group III is indium or gallium.

29. The method of claim 14, wherein
the second impurity is an element of group V.

30. The method of claim 29, wherein
the element of group V is antimony.

31. The method of claim 17, wherein
the second impurity is an element of group III.

32. The method of claim 31, wherein
the element of group III is indium or gallium.

33. The method of claim 17, wherein
the second impurity is an element of group V.

34. The method of claim 33, wherein
the element of group V is antimony.

35. The method of claim 21, wherein
the second impurity is an element of group III.

36. The method of claim 35, wherein
the element of group III is indium or gallium.

37. The method of claim 21, wherein
the second impurity is an element of group V.

38. The method of claim 37, wherein
the element of group V is antimony.
